(19) United States
(12) Patent Application Publication
(10) Pub. No.: US 2025/0125599 A1
(43) Pub. Date: Apr. 17, 2025

(54) ENCLOSURE STRUCTURALLY CONFIGURED TO PROVIDE ENHANCED ACCESS TO AN ELECTRONIC COMPONENT MOUNTED IN THE ENCLOSURE

(71) Applicant: PPC BROADBAND, INC., East Syracuse, NY (US)

(72) Inventor: Gilibaldo RUIZ, Laguna Vista, TX (US)

(73) Assignee: PPC BROADBAND, INC., East Syracuse, NY (US)

(21) Appl. No.: 18/916,507

(22) Filed: Oct. 15, 2024

Related U.S. Application Data
(60) Provisional application No. 63/543,880, filed on Oct. 12, 2023.

(51) Int. Cl. H02G 3/08; H02G 3/03

(52) U.S. Cl. CPC H02G 3/081; H02G 3/03

(57) ABSTRACT

An enclosure may include a body portion, a base portion structurally configured to be mounted to a wall portion of the body portion, a component holder portion structurally configured to be pivotally coupled with the base portion and to mountingly receive an electronic component, and a selector portion structurally configured to selectively permit relative movement between the component holder portion and the base portion. The selector portion may be structurally configured to be moved from a first position, where the component holder portion is held proximate the base portion, and a second portion, where the component holder portion is permitted to pivot away from the base portion through the range of relative movement so as to provide enhanced access to an electronic component mounted on the component holder portion.

### CROSS REFERENCE TO RELATED APPLICATION

This application claims the benefit of U.S. Provisional Application No. 63/543,880 filed Oct. 12, 2023, pending, the disclosure of which is hereby incorporated by reference herein in its entirety.

### TECHNICAL FIELD

The present disclosure is directed to a distribution enclosure and, more particularly, to a cable distribution box with a pivot mechanism that may provide enhanced access to an electronic component mounted in the box and/or aid thermal characteristics of the box.

### BACKGROUND

The proliferation of cabled connections to provide data and other signals to residential, commercial, and industrial sites has emphasized the distribution capabilities of networks. As networks expand and gain more capabilities as a result of research and development, distribution enclosures are more frequently utilized and accessed. Such heightened interaction over time can pose risks to network reliability and performance as cabling and/or network devices are accessed. Hence, there is a continued goal for cabling distribution enclosures that provide robust reliability over time with physically smaller dimensions to incur less of a footprint.

Current solutions for cabling distribution enclosures have proven inefficient and unreliable overtime. For instance, distribution enclosures can house components, such as switches, servers, amplifiers, filters, or other interconnects, that are difficult to access and correctly engage to establish a cabling network with full performance capabilities. Another challenge for some distribution enclosures involves management of environmental conditions over time, such as heat mitigation and waterproofing.

For these reasons, it may be desirable to provide an enclosure that may provide efficient management of heat over time and/or allow enhanced access to network components in the enclosure. For example, it may be desirable to provide an enclosure that may permit relative movement of an electronic component mounted in the enclosure relative to a wall portion of the enclosure so as to provide enhanced access to the electronic component. In some aspects, it may be desirable to provide an enclosure that may be structurally configured to provide an airflow path between the component holder portion and the wall portion for receiving the flow of air from the cooling portion so as to cool an electronic component mounted in the enclosure.

### SUMMARY

In accordance with various aspects of the disclosure, an enclosure may include a body portion, a cover portion structurally configured to be movingly coupled relative to the body portion between an open position and a closed position, a base portion structurally configured to be mounted to a wall portion of the body portion, a component holder portion structurally configured to be pivotally coupled with the base portion, a selector portion structurally configured to selectively permit relative movement between the component holder portion and the base portion, a pivot limiting portion structurally configured to limit a range of relative movement between the component holder portion and the base portion, and a cooling portion structurally configured to provide a flow of air in the enclosure. The component holder portion may be structurally configured to mountingly receive an electronic component, and the base portion and the component holder portion may be structurally configured to provide an airflow path between the component holder portion and the wall portion for receiving the flow of air from the cooling portion so as to cool an electronic component mounted to the component holder portion. The selector portion may be structurally configured to be moved from a first position, where the component holder portion is held proximate the base portion, and a second portion, where the component holder portion is permitted to pivot away from the base portion through the range of relative movement so as to provide enhanced access to an electronic component mounted on the component holder portion.

In some embodiments of the enclosure, the selector portion may include a fastener portion structurally configured to extend through the component holder and be coupled with the base portion so as to hold the component holder portion proximate the base portion.

In some embodiments of any of the aforementioned enclosures, the selector portion may include a latch portion configured to extend from the component holder portion and a receiving portion in the component holder, wherein the latch portion is structurally configured to engage an edge portion of the base portion, and the receiving portion is structurally configured to slidingly receive an engagement portion configured to extend from the base portion. The receiving portion may be configured to permit the engagement portion to be moved between a first position relative to the component holder portion, where the component holder portion is held proximate the base portion, and a second position relative to the component holder portion, where the component holder portion is permitted to pivot away from the base portion through the range of relative movement.

In some embodiments of any of the aforementioned enclosures, the cooling portion may include a first fan and a second fan that are disposed on opposite side wall portions of the body portion, and the first fan and the second fan may be offset from one another along a length of the opposite side wall portions so as to promote a flow of air in a first direction from one of the side wall portions toward the other side wall portion and in a second direction extending in a direction of the offset between the first fan and the second fan.

In some embodiments of any of the aforementioned enclosures, the pivot limiting portion may include a tether configured to be coupled with the base portion and the component holder portion.

In accordance with various aspects of the disclosure, an enclosure may include a body portion, a base portion structurally configured to be mounted to a wall portion of the body portion, a component holder portion structurally configured to be pivotally coupled with the base portion, a selector portion structurally configured to selectively permit relative movement between the component holder portion and the base portion, and a pivot limiting portion structurally configured to limit a range of relative movement between the component holder portion and the base portion. The component holder portion may be structurally configured to mountingly receive an electronic component, and the base portion and the component holder portion may be structurally configured to provide an air flow path between the component holder portion and the wall portion configured to receive a flow of air from a cooling portion so as to cool an electronic component mounted to the component holder portion. The selector portion may be structurally configured to be moved from a first position, where the component holder portion is held proximate the base portion, and a second portion, where the component holder portion is permitted to pivot away from the base portion through the range of relative movement so as to provide enhanced access to an electronic component mounted on the component holder portion.

In some embodiments of any of the aforementioned enclosures, the selector portion may further include a fastener portion structurally configured to extend through the component holder and be coupled with the base portion so as to hold the component holder portion proximate the base portion.

In some embodiments of any of the aforementioned enclosures, the selector portion may include a latch portion configured to extend from the component holder portion and a receiving portion in the component holder, wherein the latch portion is structurally configured to engage an edge portion of the base portion, and the receiving portion is structurally configured to slidingly receive an engagement portion configured to extend from the base portion. The receiving portion may be configured to permit the engagement portion to be moved between a first position relative to the component holder portion, where the component holder portion is held proximate the base portion, and a second position relative to the component holder portion, where the component holder portion is permitted to pivot away from the base portion through the range of relative movement.

In some embodiments of any of the aforementioned enclosures, the enclosure may further include a cooling portion structurally configured to provide a flow of air in the enclosure. In some aspects, the cooling portion may include a first fan and a second fan that are disposed on opposite side wall portions of the body portion, and the first fan and the second fan may be offset from one another along a length of the opposite side wall portions so as to promote a flow of air in a first direction from one of the side wall portions toward the other side wall portion and in a second direction extending in a direction of the offset between the first fan and the second fan.

In some embodiments of any of the aforementioned enclosures, the pivot limiting portion may include a tether configured to be coupled with the base portion and the component holder portion.

In some embodiments of any of the aforementioned enclosures, the enclosure may further include a cover portion structurally configured to be movingly coupled relative to the body portion between an open position and a closed position.

In accordance with various aspects of the disclosure, an enclosure may include a body portion, a base portion structurally configured to be mounted to a wall portion of the body portion, a component holder portion structurally configured to be pivotally coupled with the base portion and to mountingly receive an electronic component, and a selector portion structurally configured to selectively permit relative movement between the component holder portion and the base portion. The selector portion may be structurally configured to be moved from a first position, where the component holder portion is held proximate the base portion, and a second portion, where the component holder portion is permitted to pivot away from the base portion through the range of relative movement so as to provide enhanced access to an electronic component mounted on the component holder portion.

In some embodiments of any of the aforementioned enclosures, the selector portion may include a fastener portion structurally configured to extend through the component holder and be coupled with the base portion so as to hold the component holder portion proximate the base portion.

In some embodiments of any of the aforementioned enclosures, the selector portion may include a latch portion configured to extend from the component holder portion and a receiving portion in the component holder, wherein the latch portion is structurally configured to engage an edge portion of the base portion, and the receiving portion is structurally configured to slidingly receive an engagement portion configured to extend from the base portion. The receiving portion may be configured to permit the engagement portion to be moved between a first position relative to the component holder portion, where the component holder portion is held proximate the base portion, and a second position relative to the component holder portion, where the component holder portion is permitted to pivot away from the base portion through the range of relative movement.

In some embodiments of any of the aforementioned enclosures, the enclosure may further include a cooling portion structurally configured to provide a flow of air in the enclosure, and the base portion and the component holder portion may be structurally configured to provide an air flow path between the component holder portion and the wall portion configured to receive the flow of air from the cooling portion so as to cool an electronic component mounted to the component holder portion. In aspects, the cooling portion may include a first fan and a second fan that are disposed on opposite side wall portions of the body portion, and the first fan and the second fan are offset from one another along a length of the opposite side wall portions so as to promote a flow of air in a first direction from one of the side wall portions toward the other side wall portion and in a second direction extending in a direction of the offset between the first fan and the second fan.

In some embodiments of any of the aforementioned enclosures, the pivot limiting portion may include a tether configured to be coupled with the base portion and the component holder portion.

In some embodiments of any of the aforementioned enclosures, the enclosure may further include a cover portion structurally configured to be movingly coupled relative to the body portion between an open position and a closed position.

In some embodiments of any of the aforementioned enclosures, the enclosure may further include a pivot limiting portion structurally configured to limit a range of relative movement between the component holder portion and the base portion.

### BRIEF DESCRIPTION OF THE DRAWINGS

Further advantages and features of the present disclosure will become apparent from the following description and the accompanying drawings, to which reference is made.

FIG. 1 is a line representation of a network environment in which assorted embodiments of this disclosure can be practiced.

FIG. 2 is a line representation of portions of a network system that can be utilized in the environment of FIG. 1 in various embodiments of this disclosure.

FIG. 3 is a perspective view of portions of a cabling distribution enclosure configured in accordance with various embodiments of this disclosure.

FIG. 4 is a perspective view of portions of a cabling distribution enclosure arranged in accordance with some embodiments of this disclosure.

FIG. 5 is a cross-sectional view of portions of a cabling distribution enclosure configured in accordance with various embodiments of this disclosure.

FIG. 6 is a cross-sectional view of portions of a cabling distribution enclosure arranged in accordance with some embodiments of this disclosure.

FIG. 7 is a perspective view of a pivot mechanism that can be incorporated into a distribution enclosure in various embodiments of this disclosure.

FIG. 8 is a perspective view of a pivot mechanism that may be incorporated into a distribution enclosure in some embodiments of this disclosure.

FIG. 9 is a perspective view of a pivot mechanism that can be incorporated into a distribution enclosure in various embodiments of this disclosure.

FIG. 10 is a perspective view of a pivot mechanism that may be incorporated into a distribution enclosure in various embodiments of this disclosure.

FIG. 11 is a perspective view of a pivot mechanism that can be incorporated into a distribution enclosure in various embodiments of this disclosure.

FIG. 12 is a perspective view of a pivot mechanism that may be incorporated into a distribution enclosure in various embodiments of this disclosure.

### DETAILED DESCRIPTION

Reference will now be made in detail to presently preferred embodiments and methods of the present disclosure, which constitute the best modes of practicing the present disclosure presently known to the inventors. However, it is to be understood that the disclosed embodiments are merely exemplary of the present disclosure that may be embodied in various and alternative forms. Therefore, specific details disclosed herein are not to be interpreted as limiting, but merely as a representative basis for any aspect of the present disclosure and/or as a representative basis for teaching one skilled in the art to variously employ the present disclosure.

It is also to be understood that this present disclosure is not limited to the specific embodiments and methods described below, as specific components and/or conditions may, of course, vary. Furthermore, the terminology used herein is used only for the purpose of describing particular embodiments of the present disclosure and is not intended to be limiting in any way.

With conventional network distribution enclosures, component access and heat mitigation can pose difficult challenges over time. Accordingly, embodiments of the present disclosure are directed to a cabling distribution enclosure that provides a pivot mechanism that allows for efficient access to components housed in the enclosure as well as efficient mitigation of heat during operation of the components. Some embodiments arrange a cable distribution enclosure with an enclosure body, a pivot assembly, and a digital device that are configure the pivot to be housed within the enclosure body while the digital device is mounted to the pivot assembly. The pivot assembly, in some embodiments, has a pivot frame connected to a pivot base via a pivot member along with a selector configured to allow selective movement of the pivot frame and digital device relative to the pivot base to position the digital device external to the enclosure body.

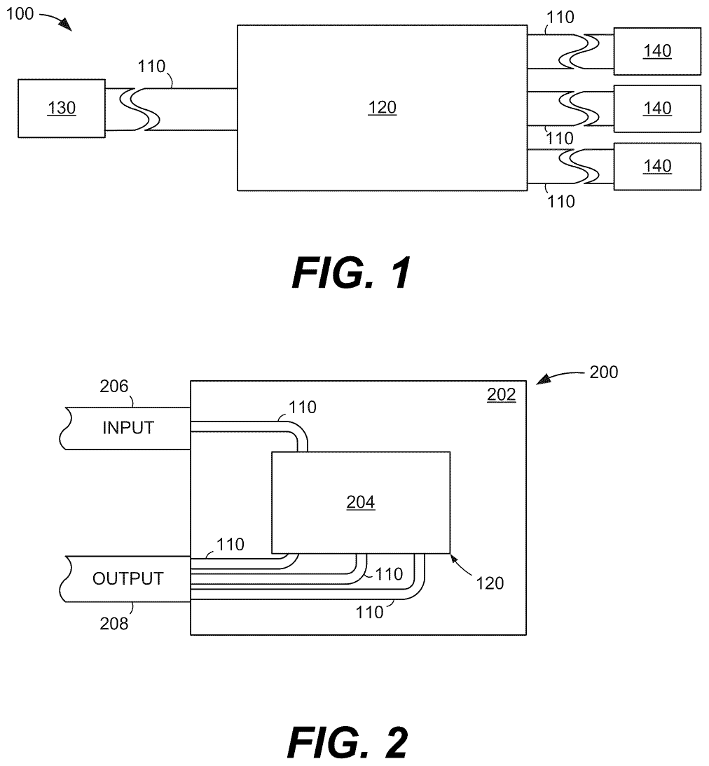

FIG. 1 displays a line representation of a network environment 100 in which assorted embodiments of a cabling distribution enclosure can be practiced. An input cable 110, such as a fiber optic, coaxial, or ethernet cable, can connect to one or more output cables 110 by an interconnect 120, such as a device, interface, adapter, or cassette. The assorted cables 110 and interconnect 120 provide one or more signal pathways that continuously extend from at least one signal source 130 to at least one destination 140.

The non-limiting environment 100 of FIG. 1 illustrate how the interconnect 120 can split an input cable 110 into multiple output cables 110 that terminate in separate destinations 140. It is contemplated that the assorted cables 110 entering, and exiting, an interconnect 120 have matching, or different, characteristics, such as diameter, type, signal latency, resistance, and length. The use of an interconnect 120 to join separate cables 110 to form one or more signal pathways between sources 130 and destinations 140 can occur anywhere, but are often contained within weather resistant enclosures to protect the integrity and longevity of the cable 110 connection provided by the interconnect 120.

FIG. 2 shows a line representation of portions of a network system 200 that can be employed in the environment 100 of FIG. 1 in accordance with various embodiments of this disclosure. The system 200 employs a unitary housing 202 to secure and protect various cables 110 as they physically engage and digitally interact through one or more interconnects 120. The non-limiting interconnect 120 shown in FIG. 2 is configured as an electronic component 204, for example, an electronic switch, server, splitter, or other digital device, that connects one or more cables 110 from an input conduit 206 to an output conduit 208. It is noted that the housing 202 may allow for any number, and type, of input cables 110 and conduits 206 that leave the housing 202 as any number, and type, of output cables 110 positioned in output conduits 208.

While the housing 202 can securely retain the digital device 204 and protect the connections and distribution of the assorted cables 110, the housing 202 can pose environmental challenges, particularly with heat and humidity. For instance, a water resistant housing 202, such as a NEMA 3R, can retain heat and humidity close to the digital device 204 over time while posing difficulties for routing electrical power to the digital device 204, which can jeopardize the performance and/or reliability of the operation of the digital device 204, particularly devices 204 that are relatively large. In addition, the housing 202, despite a relatively large physical size, may be difficult to route electrical power to the digital device.

As another exemplary operation, the housing 202 may pose access challenges corresponding with adding, removing, or changing cabling 110 configurations within the housing 202 and/or relative to the digital device 204. That is, physical access to portions of the digital device 204 and/or cabling 110 can be difficult due to the respective secured locations within the housing 202. For instance, visual and physical access to assorted ports of the digital device 204 can be obscured while the device 204 is physically secured within the housing 202, which requires the device 204 to be uninstalled and, at least partially, removed from the housing 202 to inspect and alter the interconnection configuration of the housing 202. As such, various embodiments are directed at providing increased environmental controls and more efficient access to portions of a housing 202.

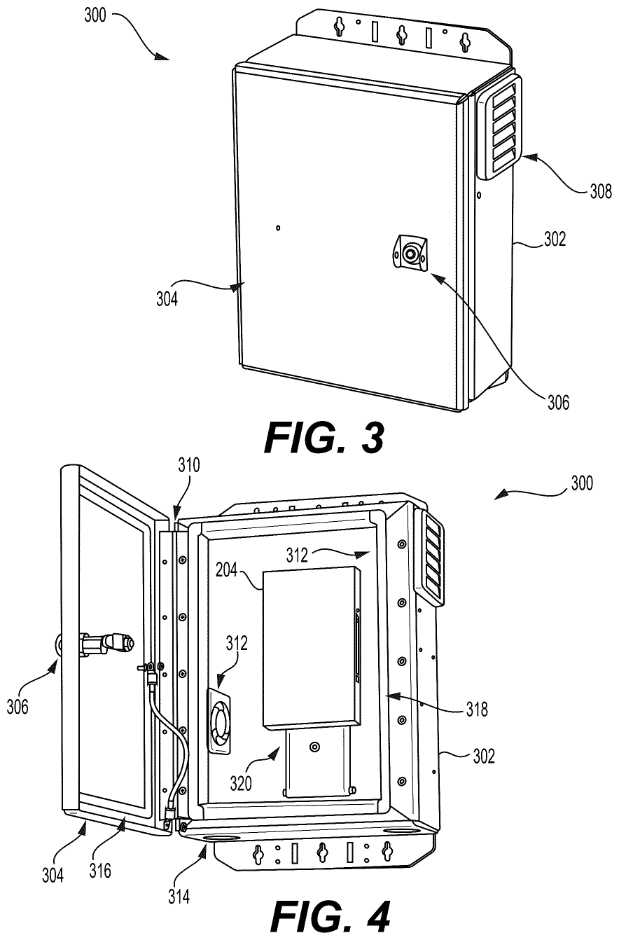

FIGS. 3-12 respectively illustrate assorted aspects of a cable distribution enclosure 300 that can be employed, for example, in the environment 100 of FIG. 1 and the system 200 of FIG. 2 in accordance with various embodiments. The perspective view of FIG. 3 conveys the enclosure 300 in a closed state and unmounted to a support structure. That is, an enclosure body or body portion 302 has an assortment of mounting apertures that are not physically attached to anything, such as a pole, wall, pillar, or eave. The closed state can be characterized as having an enclosure door or door portion or cover portion 304 in a position to completely close an interior volume defined by the enclosure body 302. It is noted that the closed position of the door 304 can provide a water resistant, or waterproof, condition for the interior volume defined by the enclosure body 302.

While not required or limiting, the enclosure door 304 may be equipped with a lockable handle 306 that selectively allows for manipulation of the door 304 relative to the body 302. The enclosure body 302 may also be equipped with a vent portion 308 that allows for one-way, or two-way, airflow while providing some resilience to water penetration for the collective enclosure 300. It is noted that some embodiments position the vent portion 308, for example, two vents, on opposite lateral sides of the enclosure body 302 to provide a desired volume of airflow through the interior cavity defined by the body 302 and door 304.

FIG. 4 illustrates the interior cavity of the distribution enclosure 300 exposed as the door 304 rotates about a hinge portion 310. The interior cavity houses an air circulation portion 312, for example, a fan, mounted proximal each enclosure vent 308, which allows for selective activation to draw air into the enclosure body 302, expel air from the enclosure body 302, or create a continuous stream of air through the enclosure body 302. One or more knockout portions 314 in the body 302 can allow a technician to efficiently pass cords, cables, and conduit into, and/or out of, the interior cavity of the enclosure body 302. A knockout portion 314 is not limited to a particular configuration and can be any selectable mechanism to allow access, such as a door, removable plate, occupied aperture, or the like.

The enclosure door 304, as shown, is equipped with a sealing portion 316, such as, for example, a gasket, seal, flange, or weatherstripping, that engages aspects of a raised lip portion 318 of the enclosure body 302. In other words, the door 304 can have one or more components that physically engage aspects of the raised lip portion 318 of the enclosure body 302 to provide secure door 304 closure as well as heightened water resiliency for the interior cavity of the enclosure body 302. Such increased water resiliency can prove beneficial in operating any digital devices 204 contained within the enclosure body 302.

By arranging the distribution enclosure 300 with heightened water resiliency and airflow manipulating components, digital devices 204 can operate reliably and at peak performance for extended periods of time. However, the increased sealing capabilities of the distribution enclosure 300 can create environmental conditions within the enclosure body 302 that jeopardize the operational performance and/or longevity of any digital devices 204 housed within the enclosure's internal cavity. For instance, heat, humidity, and changes in temperature can produce condensation and thermal regions that can be exacerbated by the production of heat from the digital device 204. Furthermore, the presence of one or more fans 312 in the enclosure body 302 may mitigate environmental conditions in some portions of the internal cavity of the body 302, but may not be sufficient to control conditions throughout the internal cavity, particularly proximal the digital device(s) 204 that produce heat during operation.

By positioning one or more digital devices 204 within the enclosure body 302, the distribution enclosure 300 can provide a diverse array of connectivity options along with efficient installation. Yet, the conventional manner of securing digital devices 204 within the enclosure body 302 can inhibit efficient access, inspection, and alteration of the connections provided by the digital device(s) 204. For instance, devices 204 can be affixed within an enclosure body 302 via a static mount, such as a fastener or secure plate, that can be difficult to remove or alter to gain visual and/or haptic access or a temporary mount, such as hook-and-loop mechanism, that can degrade over time while being difficult to maintain cabling organization. Accordingly, various embodiments of the distribution enclosure 300 provide a pivot portion or pivot assembly 320 to allow for efficient digital device 204 management and enclosure body 302 environmental control over time.

The perspective view of FIG. 4 illustrates how the pivot assembly 320 may be mounted within the internal cavity of the enclosure body 302 substantially centered between the fans 312 located on the respective opposite lateral sides of the body 302. The pivot assembly 320 may be positioned anywhere within the enclosure body 302, but various embodiments mount the pivot assembly 320 so that the attached digital device(s) 320 are respectively aligned with, and located between, the fans 312. The non-limiting embodiment shown in FIGS. 3-6 conveys how fans 312 can be vertically offset, along the longitudinal axis of the enclosure body 302, while each being aligned, laterally along the transverse axis of the enclosure body 302, with the digital device 204. As a result, airflow can be efficiently managed to cool the digital devices 204 and control the environmental conditions within the enclosure body 302.

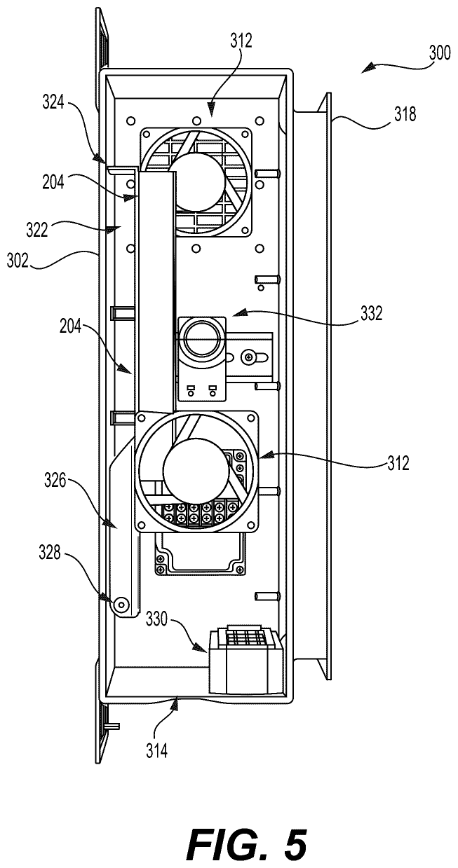

The cross-sectional side view of the distribution enclosure 300 in FIG. 5 illustrates how the pivot assembly 320 provides a cooling portion or cooling channel 322 between the digital device 204 and the enclosure body 302. The pivot assembly 320 maintains an open airflow pathway that is the cooling channel 322 with a standoff portion 324 of a component holder portion or frame portion or pivot frame 326, which can be a flange that prevents the digital device 204 from collapsing some, or all, of the cooling channel 322 in response to movement or vibration of the digital device 204. The side view of FIG. 5 further illustrates how the pivot frame 326 is mounted to the enclosure body 302 via a pivot portion or pivot member 328, which may be a pin, spring, keyed protrusion, or other mechanism providing an axis of rotation for the pivot frame 326.

In accordance with various embodiments of the distribution enclosure 300, a power center 330 is housed within the enclosure body 302 along with at least one sensor 332. The power center 330 may be an AC or DC source of electricity and, in some embodiments, is a surge protector power strip that provides multiple grounded, or ungrounded, outlets to provide electrical power to one or more digital devices 204. The position of the power center 330 proximal the knockout portions 314 of the enclosure body 302 allows for efficient cable management and increased enclosure organization compared to routing electrical power cables through the knockout portions 314 from external sources of electrical power.

Any number, type, and position of sensors 332 can complement the power center 330 by providing information about the current conditions within the enclosure body 302, such as temperature, humidity, and airflow volume. Such information can be employed to selectively activate and operate the assorted enclosure fans 312 and vents 308. For instance, data gathered locally, or remotely, in real-time, and/or over time, by one or more sensors 332 can be used to optimize the volume and temperature of airflow in the cooling channel 322 by manipulating the direction and/or speed of one or more fans 312 and/or the degree of vent 308 opening.

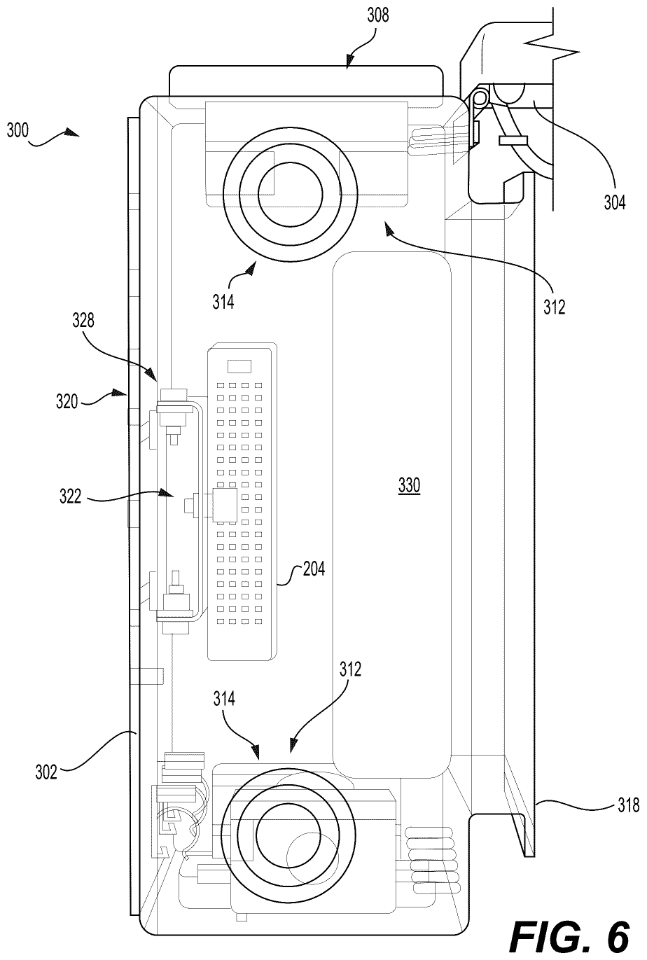

In FIG. 6, a cross-sectional bottom view of the distribution enclosure 300 conveys how the cooling channel 322 continuously extends throughout the pivot frame 326 in a vertical direction, along the longitudinal axis of the enclosure body 302, and in the transverse direction, perpendicular to the vertical direction, between the digital device 204 and the enclosure body 302. The bottom view of FIG. 6 further conveys how knockout portions 314 can be positioned relative to the power center 330 and pivot assembly 320.

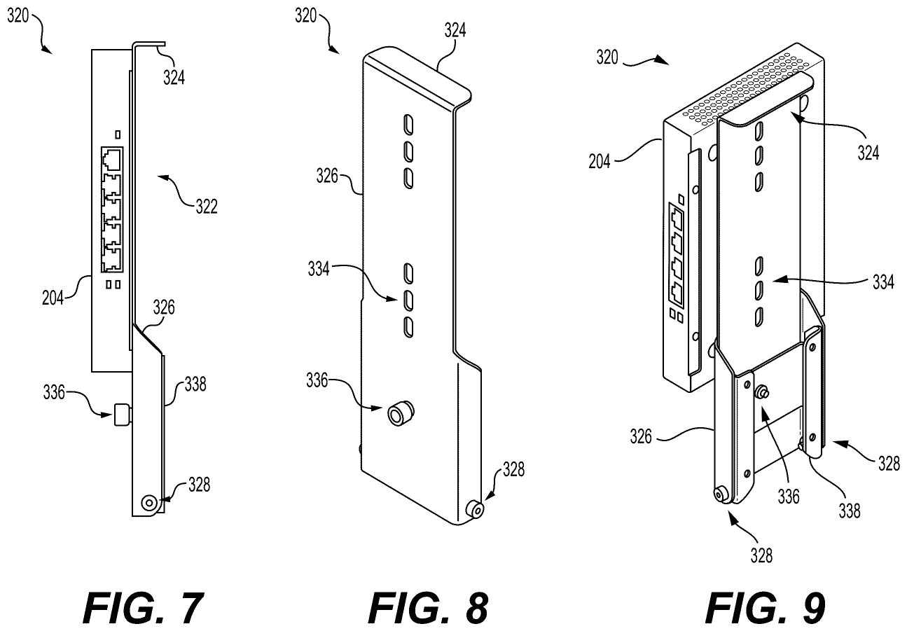

Turning to FIGS. 7-10, the respective perspective views illustrate assorted aspects of a pivot assembly 320 that can be utilized in the distribution enclosure 300 of FIGS. 3-6 in accordance with various embodiments. The side view of FIG. 7 shows how the pivot assembly 320 can be arranged so that the digital device 204 is statically mounted onto the pivot frame 326. The device 204 mounting can be achieved with any fastener, adhesive, or clip that may engage one or more mounting apertures 334 of the frame 326, as shown in FIGS. 8-11.

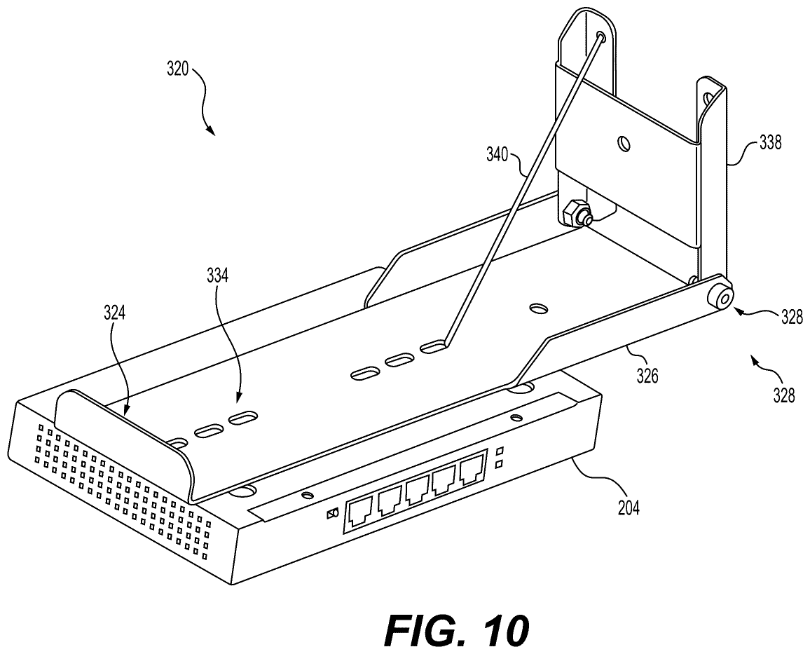

The configuration of the pivot assembly 320 provides both the cooling channel 322 and an articulation selector portion or selector 336 that can be manipulated, either manually or automatically, to allow the pivot frame 326 to rotate about the pivot member 328, as shown in FIG. 10. The selector 336 is not limited to a particular feature, component, or mechanism, but in some embodiments is a screw that engages a portion of a base portion or pivot base 338 to either secure the frame 326 in an upright configuration, as shown in FIGS. 7-9, or allow the frame 326 to rotate, as shown in FIG. 10.

The ability to rotate the frame 326 allows portions of the digital device 204, such as the ports shown in FIGS. 7, 9 and 10, to be efficiently viewed, inspected, and physically manipulated. In contrast, a statically mounted digital device 204 can have portions encumbered from visual and/or physical inspection due to the size and shape of the enclosure body 302 in which the device 204 is mounted. Through the manipulation of the selector 336, the pivot frame 326 efficiently moves the digital device 204 so that at least the device ports are present, visible, and accessible outside the enclosure body 302. Hence, the pivot assembly 320 allows for secure placement within the enclosure body 302 when the selector 336 is in a first, locked, position and allows for rotation to a position outside the enclosure body 302 when the selector 336 is in a second, unlocked, position.

To clarify, the pivot assembly 320 arrangement shown in FIGS. 7-9 correspond to a locked selector 336 configuration where the selector 336 physically engages both the pivot frame 326 and pivot base 338. The locked selector 336 configuration allows the pivot assembly 320 to remain securely in place within an enclosure body 302. The unlocked selector 336 configuration, as shown in FIG. 10, brings the digital device 204 outside the enclosure body 302 while securely attached to the pivot frame 326, base 338, and enclosure body 302, which promotes efficient access, connectivity, and cabling organization. A pivot limiting portion 340, such as, for example, the tether shown in FIG. 10, a physical stop, spring, or catch, can serve to prevent over-rotation of the pivot frame 326 about the pivot member 328, which can further secure the digital device 204 outside the enclosure body 302 for inspection and physical interaction.

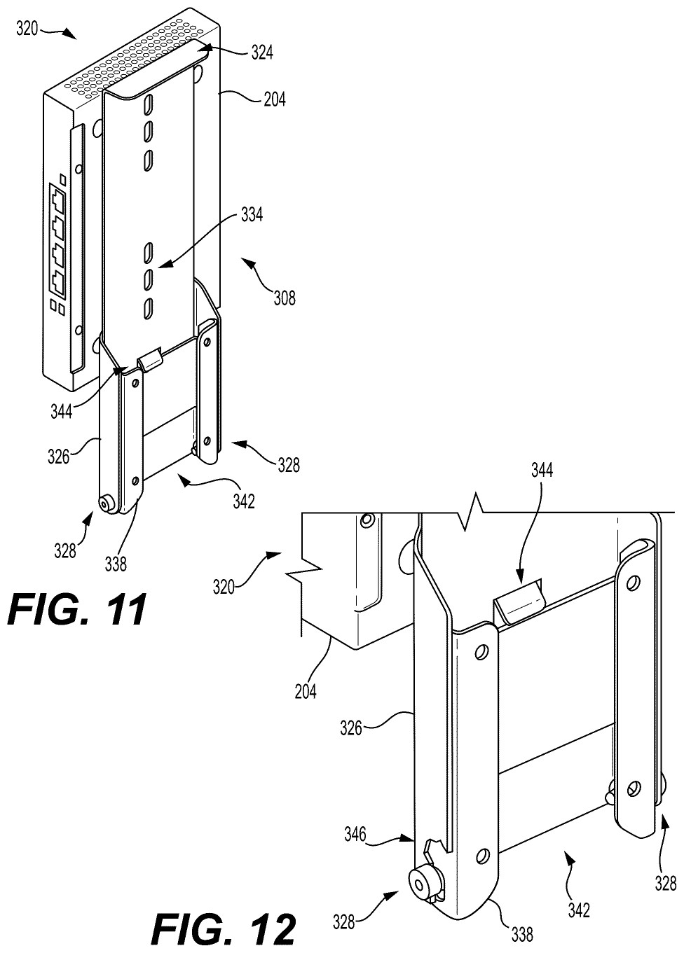

It is noted that the selector 336 shown in FIGS. 7-10 is not required. FIGS. 11 and 12 respectively illustrate an alternate selector 342 that can be employed alone, or in combination with the screw-type selector 336, to selectively secure the pivot frame 326 to the pivot base 338. The selector 342 shown in FIGS. 11 and 12 comprises a latch portion 344, for example, a stop tab, that extends from the component holder portion 326 and a receiving portion 346, for example, a slot or notch in a wall portion of the component holder portion 326. The receiving portion 346 is configured to permit sliding movement of an engagement portion 328 that extends from the base portion 338 relative to the component holder portion. FIG. 12 conveys how the slot 346 permits the sliding movement of an engagement portion 328 relative to the component holder portion operates in response to upward force, along a direction opposite to gravity and parallel to the longitudinal axis of the frame 326 such that the latch portion 344 disengages from the edge of the base portion 338 so as to permit the component holder portion 326 to pivot relative to the base portion 338. FIG. 11 conveys how the tab 344 is configured to engages the base portion 338 as the frame 326 drops down from the position shown in FIG. 12 via the slot 346 due to gravity.

With the selector 342 shown in FIGS. 11 and 12, a technician can manipulate the pivot frame 326 with one hand, which can increase the efficiency of digital device 204 access and interaction. In comparison, the screw-type selector 336 of FIGS. 7-10 can provide a more physically secure engagement of the pivot frame 326 to the pivot base 338, but can require two hands of a technician to properly set the selector 336. Regardless of the selector 336/342 configuration, the ability to set the position of the pivot frame 326 relative to the pivot base 338 and the enclosure body 302 in which the pivot assembly 320 is housed.

Also, with respect to the various embodiments of the present disclosure, the components of the cable 110 can be constructed of various materials which have some degree of elasticity or flexibility. The elasticity enables the cable 110 to flex or bend in accordance with broadband communications standards, installation methods or installation equipment. Also, the radial thicknesses of the cable 110, the signal pathway conductor 130, insulator 140, any shielding layers 150, and the outer jacket 160 can vary based upon parameters corresponding to broadband communication standards or installation equipment.

Additional embodiments include any one of the embodiments described above, where one or more of its components, functionalities or structures is interchanged with, replaced by or augmented by one or more of the components, functionalities or structures of a different embodiment described above. It should be understood that various changes and modifications to the embodiments described herein will be apparent to those skilled in the art. Such changes and modifications can be made without departing from the spirit and scope of the present disclosure and without diminishing its intended advantages. It is therefore intended that such changes and modifications be covered by the appended claims.

Although several embodiments of the disclosure have been disclosed in the foregoing specification, it is understood by those skilled in the art that many modifications and other embodiments of the disclosure will come to mind to which the disclosure pertains, having the benefit of the teaching presented in the foregoing description and associated drawings. It is thus understood that the disclosure is not limited to the specific embodiments disclosed herein above, and that many modifications and other embodiments are intended to be included within the scope of the appended claims. Moreover, although specific terms are employed herein, as well as in the claims which follow, they are used only in a generic and descriptive sense, and not for the purposes of limiting the present disclosure, nor the claims which follow.

What is claimed is:

1. An enclosure structurally configured to provide enhanced access to an electronic component mounted in the enclosure, comprising:
a body portion;
a cover portion structurally configured to be movingly coupled relative to the body portion between an open position and a closed position;
a base portion structurally configured to be mounted to a wall portion of the body portion;
a component holder portion structurally configured to be pivotally coupled with the base portion;
a selector portion structurally configured to selectively permit relative movement between the component holder portion and the base portion;
a pivot limiting portion structurally configured to limit a range of relative movement between the component holder portion and the base portion;
a cooling portion structurally configured to provide a flow of air in the enclosure;
wherein the component holder portion is structurally configured to mountingly receive an electronic component;
wherein the base portion and the component holder portion are structurally configured to provide an airflow path between the component holder portion and the wall portion for receiving the flow of air from the cooling portion so as to cool an electronic component mounted to the component holder portion; and
wherein the selector portion is structurally configured to be moved from a first position, where the component holder portion is held proximate the base portion, and a second portion, where the component holder portion is permitted to pivot away from the base portion through the range of relative movement so as to provide enhanced access to an electronic component mounted on the component holder portion.

2. The enclosure of claim 1, wherein the selector portion comprises a fastener portion structurally configured to extend through the component holder and be coupled with the base portion so as to hold the component holder portion proximate the base portion.

3. The enclosure of claim 1, wherein the selector portion comprises a latch portion configured to extend from the component holder portion and a receiving portion in the component holder, wherein the latch portion is structurally configured to engage an edge portion of the base portion, and the receiving portion is structurally configured to slidingly receive an engagement portion configured to extend from the base portion; and
wherein the receiving portion is configured to permit the engagement portion to be moved between a first position relative to the component holder portion, where the component holder portion is held proximate the base portion, and a second position relative to the component holder portion, where the component holder portion is permitted to pivot away from the base portion through the range of relative movement.

4. The enclosure of claim 1, wherein the cooling portion includes a first fan and a second fan that are disposed on opposite side wall portions of the body portion; and
wherein the first fan and the second fan are offset from one another along a length of the opposite side wall portions so as to promote a flow of air in a first direction from one of the side wall portions toward the other side wall portion and in a second direction extending in a direction of the offset between the first fan and the second fan.

5. The enclosure of claim 1, wherein the pivot limiting portion comprises a tether configured to be coupled with the base portion and the component holder portion.

6. An enclosure structurally configured to provide enhanced access to an electronic component mounted in the enclosure, comprising:
a body portion;
a base portion structurally configured to be mounted to a wall portion of the body portion;
a component holder portion structurally configured to be pivotally coupled with the base portion;
a selector portion structurally configured to selectively permit relative movement between the component holder portion and the base portion;
a pivot limiting portion structurally configured to limit a range of relative movement between the component holder portion and the base portion;
wherein the component holder portion is structurally configured to mountingly receive an electronic component;
wherein the base portion and the component holder portion are structurally configured to provide an air flow path between the component holder portion and the wall portion configured to receive a flow of air from a cooling portion so as to cool an electronic component mounted to the component holder portion; and
wherein the selector portion is structurally configured to be moved from a first position, where the component holder portion is held proximate the base portion, and a second portion, where the component holder portion is permitted to pivot away from the base portion through the range of relative movement so as to provide enhanced access to an electronic component mounted on the component holder portion.

7. The enclosure of claim 6, wherein the selector portion comprises a fastener portion structurally configured to extend through the component holder and be coupled with the base portion so as to hold the component holder portion proximate the base portion.

8. The enclosure of claim 6, wherein the selector portion comprises a latch portion configured to extend from the component holder portion and a receiving portion in the component holder, wherein the latch portion is structurally configured to engage an edge portion of the base portion, and the receiving portion is structurally configured to slidingly receive an engagement portion configured to extend from the base portion; and
wherein the receiving portion is configured to permit the engagement portion to be moved between a first position relative to the component holder portion, where the component holder portion is held proximate the base portion, and a second position relative to the component holder portion, where the component holder portion is permitted to pivot away from the base portion through the range of relative movement.

9. The enclosure of claim 6, further comprising a cooling portion structurally configured to provide a flow of air in the enclosure.

10. The enclosure of claim 9, wherein the cooling portion includes a first fan and a second fan that are disposed on opposite side wall portions of the body portion; and
wherein the first fan and the second fan are offset from one another along a length of the opposite side wall portions so as to promote a flow of air in a first direction from one of the side wall portions toward the other side wall portion and in a second direction extending in a direction of the offset between the first fan and the second fan.

11. The enclosure of claim 6, wherein the pivot limiting portion comprises a tether configured to be coupled with the base portion and the component holder portion.

12. The enclosure of claim 6, further comprising a cover portion structurally configured to be movingly coupled relative to the body portion between an open position and a closed position.

13. An enclosure structurally configured to provide enhanced access to an electronic component mounted in the enclosure, comprising:
a body portion;
a base portion structurally configured to be mounted to a wall portion of the body portion;
a component holder portion structurally configured to be pivotally coupled with the base portion and to mountingly receive an electronic component;
a selector portion structurally configured to selectively permit relative movement between the component holder portion and the base portion; and
wherein the selector portion is structurally configured to be moved from a first position, where the component holder portion is held proximate the base portion, and a second portion, where the component holder portion is permitted to pivot away from the base portion through the range of relative movement so as to provide enhanced access to an electronic component mounted on the component holder portion.

14. The enclosure of claim 13, wherein the selector portion comprises a fastener portion structurally configured to extend through the component holder and be coupled with the base portion so as to hold the component holder portion proximate the base portion.

15. The enclosure of claim 13, wherein the selector portion comprises a latch portion configured to extend from the component holder portion and a receiving portion in the component holder, wherein the latch portion is structurally configured to engage an edge portion of the base portion, and the receiving portion is structurally configured to slidingly receive an engagement portion configured to extend from the base portion; and
wherein the receiving portion is configured to permit the engagement portion to be moved between a first position relative to the component holder portion, where the component holder portion is held proximate the base portion, and a second position relative to the component holder portion, where the component holder portion is permitted to pivot away from the base portion through the range of relative movement.

16. The enclosure of claim 13, further comprising a cooling portion structurally configured to provide a flow of air in the enclosure; and
wherein the base portion and the component holder portion are structurally configured to provide an air flow path between the component holder portion and the wall portion configured to receive the flow of air from the cooling portion so as to cool an electronic component mounted to the component holder portion.

17. The enclosure of claim 16, wherein the cooling portion includes a first fan and a second fan that are disposed on opposite side wall portions of the body portion; and
wherein the first fan and the second fan are offset from one another along a length of the opposite side wall portions so as to promote a flow of air in a first direction from one of the side wall portions toward the other side wall portion and in a second direction extending in a direction of the offset between the first fan and the second fan.

18. The enclosure of claim 13, wherein the pivot limiting portion comprises a tether configured to be coupled with the base portion and the component holder portion.

19. The enclosure of claim 13, further comprising a cover portion structurally configured to be movingly coupled relative to the body portion between an open position and a closed position.

20. The enclosure of claim 13, further comprising a pivot limiting portion structurally configured to limit a range of relative movement between the component holder portion and the base portion.
